(19) United States
(12) Patent Application Publication
(10) Pub. No.: US 2020/0387641 A1
(43) Pub. Date: Dec. 10, 2020

(54) METHOD, AND INFORMATION PROCESSING APPARATUS

(71) Applicant: FUJITSU LIMITED, Kawasaki-shi, (JP)

(72) Inventors: Shogo Fujimori, Yamato (JP); Mie KOYAMA, Kawasaki (JP)

(73) Assignee: FUJITSU LIMITED, Kawasaki-shi (JP)

(21) Appl. No.: 16/888,899

(22) Filed: Jun. 1, 2020

(30) Foreign Application Priority Data
Jun. 6, 2019 (JP) 2019-106300

(51) Int. Cl. G06F 30/10; G02B 27/00

(52) U.S. Cl. CPC G06F 30/10; G02B 27/0012

(57) ABSTRACT

A recording medium stores a lens design program for causing a computer to execute a process including: obtaining a curvature and a first conic with respect to two lens surfaces in which light beams inputted to the optical member become parallel light beams when the optical member is in a first medium; obtaining, based on the obtained curvature, a distance between the two lens surfaces and a second conic that cause the light beams inputted to the optical member to focus at a center between the two lens surfaces when the optical member is in a second medium; and obtaining combinations of optical coupling efficiency in the first medium and the second medium in a case where the optical member based on the obtained curvature and the obtained distance is set between a light emitter of light beams and a light receiver.

### CROSS-REFERENCE TO RELATED APPLICATION

This application is based upon and claims the benefit of priority of the prior Japanese Patent Application No. 2019-106300, filed on Jun. 6, 2019, the entire contents of which are incorporated herein by reference.

### FIELD

The embodiments discussed herein are related to a recording medium, a lens design method, and an information processing apparatus.

### BACKGROUND

In a server system or the like, an optical module has been used in some cases for data transmission with the advent of high density packaging and high speed processing. For the optical module, a lens to be used between a light emitting element and a light receiving unit in the optical module is designed in such a manner as to efficiently transmit optical signals.

Japanese Laid-open Patent Publication No. 2010-128027; Japanese Laid-open Patent Publication No. 09-43401; and Japanese Laid-open Patent Publication No. 2016-133572 are examples of related art.

### SUMMARY

According to an aspect of the embodiments, a non-transitory computer-readable recording medium stores therein a lens design program for causing a computer to execute a process, the process includes: obtaining a curvature and a first conic with respect to two lens surfaces of input and output of an optical member in which light beams inputted to the optical member become parallel light beams when the optical member is in a first medium; obtaining, based on the obtained curvature, a distance between the two lens surfaces and a second conic that cause the light beams inputted to the optical member to focus at a center between the two lens surfaces when the optical member is in a second medium; obtaining combinations of optical coupling efficiency in the first medium and the second medium in a case where the optical member based on the obtained curvature and the obtained distance is set between a light emitter of light beams and a light receiver, and then the conic of the two lens surfaces is changed between the first conic and the second conic; and outputting the obtained curvature, the obtained distance, and a third conic of the two lens surfaces that brings coupling efficiency satisfying a predetermined condition among the obtained combinations of coupling efficiency.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is an explanatory diagram describing an outline about a lens design of an embodiment;

FIG. 2 is an explanatory diagram describing a lens block by a lens design of the embodiment;

FIG. 3 is a block diagram illustrating an example of a functional configuration of an information processing apparatus according to the embodiment;

FIG. 4A is a flowchart illustrating an example of operations of an information processing apparatus according to the embodiment;

FIG. 4B is a flowchart illustrating an example of operations of an information processing apparatus according to the embodiment;

FIG. 4C is a flowchart illustrating an example of operations of an information processing apparatus according to the embodiment;

FIG. 4D is a flowchart illustrating an example of operations of an information processing apparatus according to the embodiment;

FIG. 5 is a block diagram illustrating an example of a computer configured to execute a lens design program; and

FIG. 6 is an explanatory diagram describing a lens block according to a lens design of related art.

### DESCRIPTION OF EMBODIMENTS

Regarding the lens design, there is a technique to provide a lens having heat resistance. Further, there is a technique in which provided are a crystal lens and an optical element that are strong against a change in wavelength of a laser, and an optical-pickup optical system. There exists a technique to provide an optical system that is able to take a picture with respect to a plurality of media having different refractive indices, by moving a lens group along an optical axis when a medium is changed.

In a server system or the like, a cooling effect brought by immersion is used in some case to deal with heat to be generated. In the case of the immersion described above, an optical module is also used in a cooling liquid (refrigerant) Instead of air.

However, in the above-mentioned lens design of related art, the lens is assumed to be used in the air, and is designed to be optimized for the use under the environment in the air. Because of this, under the immersion environment, coupling efficiency may decrease and transmission quality of optical signals may deteriorate. Further, in a case where there is provided a mechanism or the like for moving a lens group along the optical axis when the medium is changed, the cost may considerably increase.

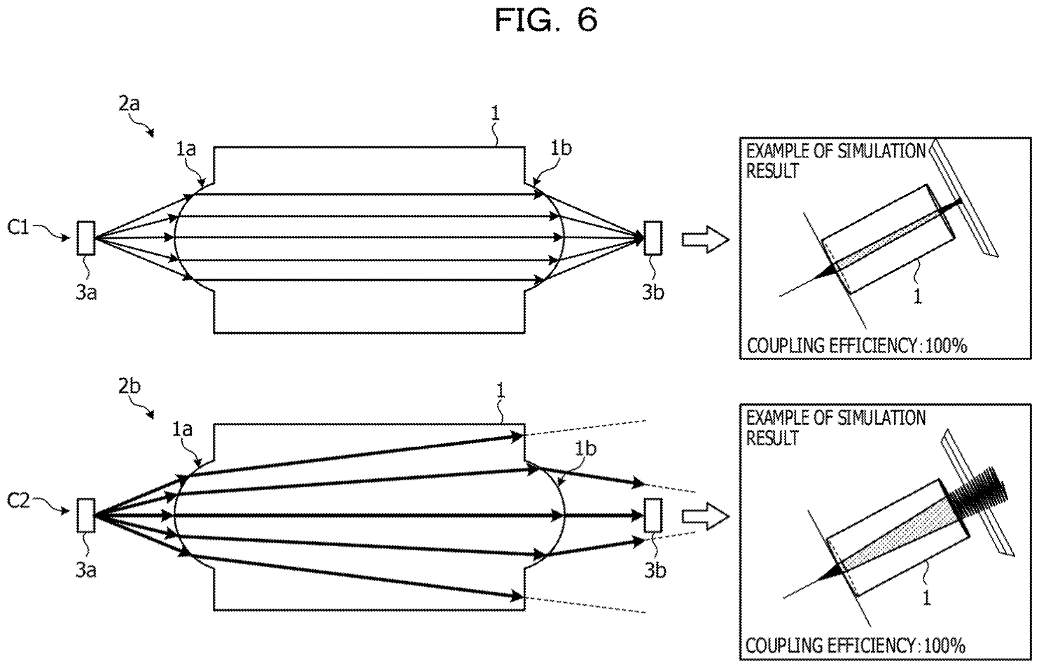

FIG. 6 is an explanatory diagram describing a lens block according to a lens design of related art. In FIG. 6, a case C1 in the upper stage is an example in which a lens block 1 is set in a medium (air) 2a, and a case C2 in the lower stage is an example in which the lens block 1 is set in a medium (liquid) 2b.

As illustrated in the case C1 of FIG. 6, in the lens block 1, a curvature and a conic of a lens surface 1a are designed such that, in the medium (air) 2a, light beams entering from a light emitting element 3a through the lens surface 1a are made to be parallel light beams by the lens design of related art. A curvature and a conic of a lens surface 1b are designed such that light beams radiated from the lens surface 1b of the lens block 1 toward the medium (air) 2a are focused on a light receiving unit 3b. Accordingly, in the medium (air) 2a, an optical signal that arrives at the light receiving unit 3b from the light emitting element 3a through the lens block 1 has a coupling efficiency of 100%.

The lens block 1 designed in this manner has a different refractive index in the medium (liquid) 2b from that in the medium (air) 2a, and thus light beams entering through the lens surface 1a do not become parallel light beams but spread excessively. Therefore, as illustrated in the case C2 of FIG. 6, in the medium (liquid) 2b, the coupling efficiency of the optical signal that arrives at the light receiving unit 3b from the light emitting element 3a through the lens block 1 is lowered (for example, lowered from 100% to 2.4%).

For example, in a multi-channel optical module, an array (VCSEL array or the like) of the light emitting elements 3a is normally arranged at an interval of 250 μm. Due to this, since the upper limit of the lens diameter is also restricted to 250 μm, a problem that not all of the light beams are received by the light receiving unit 3b is likely to occur.

It is an object of the disclosure, in one aspect, to provide a lens design program, a lens design method, and an information processing apparatus that are able to support the design of a lens for achieving preferred coupling efficiency in different media.

Hereinafter, a lens design program, a lens design method, and an information processing apparatus according to an embodiment will be described with reference to the accompanying drawings. In the embodiment, configurations having the same functions are denoted by the same reference signs, and the redundant description thereof is omitted. A lens design program, a lens design method, and an information processing apparatus to be described in the embodiment below are merely illustrative and are not intended to limit the embodiment. In addition, the following embodiments may be combined as appropriate to the extent that they are not inconsistent with each other.

[Outline]

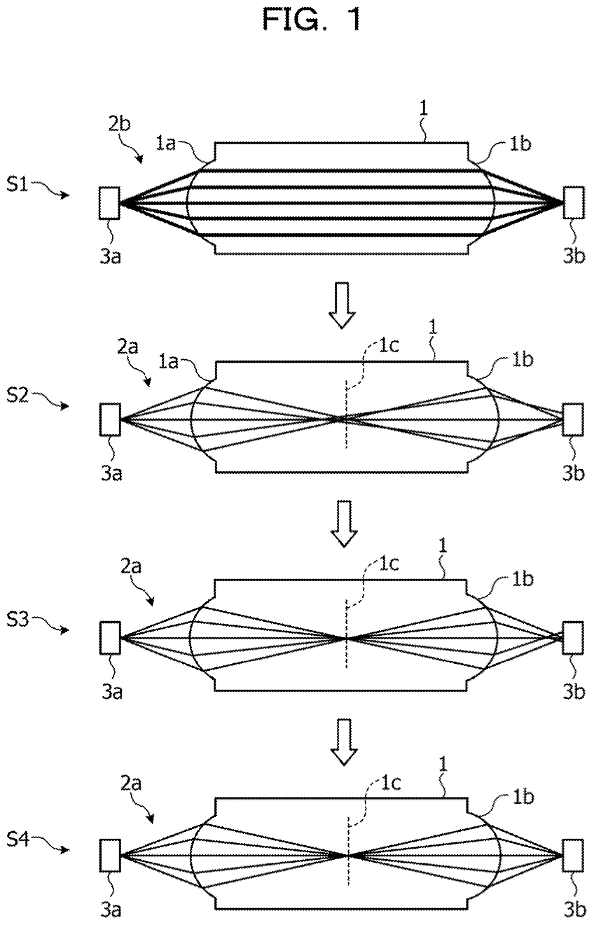

FIG. 1 is an explanatory diagram describing an outline about a lens design of the embodiment. As illustrated in FIG. 1, in the present embodiment, as an example, a lens associated with a lens block 1 of an optical module used for data transmission of a server system or the like is designed.

For example, the lens block 1 is an example of an optical member that is used between a light emitting element 3a and a light receiving unit 3b configured to perform data transmission by optical signals. The lens block 1 includes a lens surface 1a on an input side to which light from the light emitting element 3a is inputted and a lens surface 1b on an output side through which the light having passed through the lens block 1 is outputted. In the lens design, by using an optical simulation by a known ray-tracing method, a curvature, a conic constant (hereinafter referred to as a conic), a distance between the lens surfaces 1a and 1b, and the like are designed with respect to two lens surfaces 1a and 1b of input and output of the lens block 1.

For example, with respect to the lens surfaces 1a and 1b, a curvature (R) and a conic (K₁), by which the light beams inputted to the lens block 1 are made to become parallel light beams, are obtained, when the lens block 1 is set in a medium (liquid) 2b used as a refrigerant in the immersion environment (S1).

Next, the environment (medium) around the lens block 1 is changed from the medium (liquid) 2b to a medium (air) 2a. Then, based on the obtained curvature (R), a distance (AB) between the lens surfaces 1a and 1b, in which the focal point of the light beams inputted to the lens block 1 is a center 1c between the lens surfaces 1a and 1b, is obtained, when the lens block 1 is set in the medium (air) 2a (S2).

When the medium (liquid) 2b is changed to the medium (air) 2a, a spherical aberration is generated. Accordingly, obtained is a conic (K₂) for causing the spherical aberration to be minimized at the center 1c (focal position) of the light beams having passed through the lens surface 1a in the medium (air) 2a (S3).

Then, the conics of the lens surfaces 1a and 1b are combined in a range from K₁ to K₂ to carry out the optical simulation, thereby obtaining optical coupling efficiency in each of the medium (air) 2a and the medium (liquid) 2b (S4).

For example, the lens block 1 based on the obtained curvature (R) and distance (AB) is set between the light emitting element 3a and the light receiving unit 3b, and at the respective refractive indices of the medium (air) 2a and the medium (liquid) 2b, the optical simulation is carried out while changing the conics of the lens surfaces 1a and 1b in the range from K₁ to K₂. Thus, combinations of optical coupling efficiency in the medium (air) 2a and the medium (liquid) 2b are obtained. Then, of the obtained combinations of coupling efficiency, a combination of the conics of the lens surfaces 1a and 1b having the highest coupling efficiency is outputted to a display, a file, and the like along with the obtained curvature (R) and distance (AB).

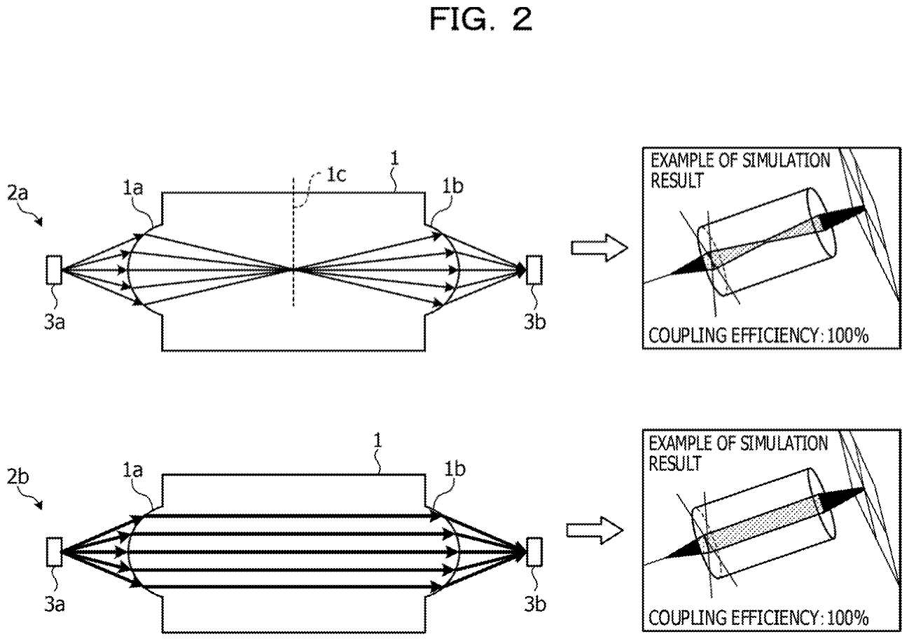

FIG. 2 is an explanatory diagram describing the lens block 1 by the lens design of the embodiment. As illustrated in FIG. 2, the lens block 1 is formed based on the values (the curvature (R) of the lens surfaces 1a and 1b, the conic thereof, and the distance (AB)) outputted in the lens design. Therefore, the lens block 1 is able to transmit the light from the light emitting element 3a to the light receiving unit 3b with high coupling efficiency in the different media of the medium (air) 2a and the medium (liquid) 2b. For example, by applying the lens block 1 to an optical module of a server system or the like, it is possible to efficiently transmit optical signals without generating a cost for providing an additional mechanism or the like, in any of the cases of usage in the air environment and in the immersion environment.

[Functional Configuration]

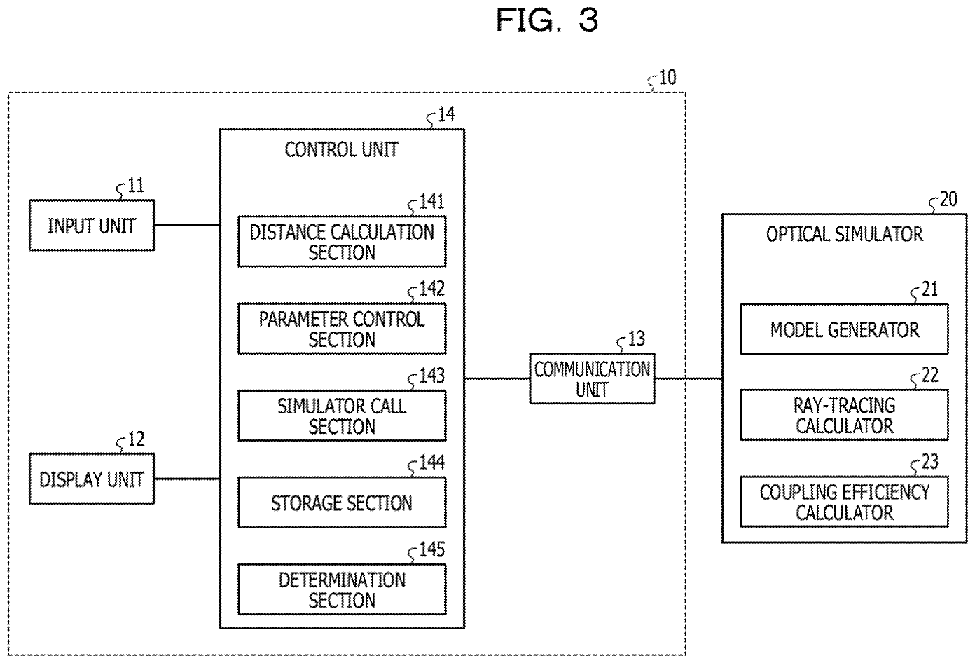

FIG. 3 is a block diagram illustrating an example of a functional configuration of an information processing apparatus according to the embodiment. As illustrated in FIG. 3, an information processing apparatus 10 is, for example, a personal computer (PC), and includes an input unit 11, a display unit 12, a communication unit 13, and a control unit 14.

The input unit 11 is a processing unit configured to carry out input processing of various data that is inputted from a user via an input device or the like such as a keyboard. For example, the input unit 11 accepts the input of various data relating to the lens design, and outputs the inputted data to the control unit 14. For example, as the data relating to the lens design that is allowed to be inputted to the input unit 11, refractive index information, light emitting element information, lens size information, light receiving unit information, determination values, and the like are cited.

The refractive index information includes a refractive index of the medium (air) 2a (for example, 1.0), a refractive index of the medium (liquid) 2b (for example, 1.28), a refractive index of lens material of the lens block 1 (for example, 1.6), and the like.

The light emitting element information is information about the light emitting element 3a, and includes a light emitting diameter (for example, ϕ12 μm), a light spread angle (for example, 11 degrees), a wavelength (for example, 850 nm), and the like.

The lens size information is information about the lens surfaces 1a and 1b, and includes a lens radius (for example, 125 μm), a lens surface usage rate (for example, 0.8), and the like.

The light receiving unit information is information about the light receiving unit 3b, and includes a light receiving unit diameter (for example, ϕ50 nm), and the like. The determination values are threshold values and the like about the lens design processing, and include an allowable lower limit value (for example, 0.85) of the coupling efficiency, and the like.

The display unit 12 is a processing unit configured to perform display operation on a display or the like under the control of the control unit 14. For example, the display unit 12 displays the information such as the curvatures (R), the distance (AB), and the combinations of the conics of the lens surfaces 1a and 1b, which are obtained by the control unit 14. For example, the display unit 12 is an example of an output unit. As for the output, a configuration in which the output is displayed on a display from the display unit 12 is exemplified in the present embodiment. However, needless to say, the configuration may be such that the output is printed on a paper medium, is outputted on a file, or the like.

Under the control of the control unit 14, the communication unit 13 communicates with an external device that is coupled regardless of wired coupling or wireless coupling. The communication unit 13 is a communication interface or the like such as a network interface card (NIC), and communicates with an optical simulator 20 coupled via a communication network such as a local area network (LAN).

The control unit 14 is a processing unit configured to manage the overall processing of the lens block 1. The control unit 14 is implemented by, for example, a central processing unit (CPU) or a microprocessor unit (MPU) running a program stored in an internal storage device while using a random-access memory (RAM) as a workspace. The control unit 14 may also be implemented as, for example, an integrated circuit, such as an application-specific integrated circuit (ASIC) or a field-programmable gate array (FPGA).

The control unit 14 includes a distance calculation section 141, a parameter control section 142, a simulator call section 143, a storage section 144, and a determination section 145, and carries out processing related to the aforementioned S1 to S4. The distance calculation section 141, the parameter control section 142, the simulator call section 143, and the determination section 145 are an example of an electronic circuit included in a processor, an example of processing carried out by the processor, and the like.

The distance calculation section 141 is a processing unit configured to perform calculation on various distances based on data relating to the lens design inputted from the input unit 11. For example, the distance calculation section 141 calculates a distance from the light emitting element 3a to the lens surface 1a, a distance from the lens surface 1b to the light receiving unit 3b, a focal length of the lens surfaces 1a and 1b, a distance between the lens surfaces 1a and 1b, and the like.

The parameter control section 142 is a processing unit configured to control various parameters of the optical simulation in the optical simulator 20 in the processing related to S1 to S4. For example, in S1, the simulator call section 143 reads out the refractive index of the medium (liquid) 2b and the refractive index of the lens material of the lens block 1 from the refractive index information, and takes the refractive indices having been read out as parameters when obtaining, by using the optical simulator 20, the curvature (R) and the conic (K₁) of the lens surfaces 1a and 1b for causing the light beams inputted to the lens block 1 to become parallel light beams.

Further, in S2, the simulator call section 143 reads out the refractive index of the medium (air) 2a and the refractive index of the lens material of the lens block 1 from the refractive index information, and takes the refractive indices having been read out as parameters along with the curvature (R) obtained in S1 when obtaining the distance (AB) between the lens surfaces 1a and 1b. In S3, the simulator call section 143 changes the conic of the lens surfaces 1a and 1b as appropriate when obtaining the conic (K₂) for causing the spherical aberration to be minimized at the center 1c (focal position) by repeating the optical simulation.

In S4, the simulator call section 143 assumes that the lens block 1 based on the curvature (R) obtained in S1 and the distance (AB) obtained in S2 is set at a location between the light emitting element 3a and the light receiving unit 3b, and takes the location as parameters to which the refractive indices of the medium (air) 2a and the medium (liquid) 2b are applied. Then, the simulator call section 143 appropriately changes the conic of the lens surfaces 1a and 1b in a range from K₁ to K₂ to carry out the optical simulation by the optical simulator 20.

The simulator call section 143 is a processing unit configured to carry out the optical simulation by calling the optical simulator 20 coupled via the information processing apparatus 10. For example, the simulator call section 143 calls the optical simulator 20 and reports thereto various kinds of parameters for the optical simulation based on the control of the parameter control section 142, and requests the optical simulator 20 to execute the optical simulation. Then, the simulator call section 143 acquires a result of the optical simulation executed by the optical simulator 20.

The storage section 144 is a RAM or the like configured to provide a workspace of processing, and stores various kinds of data (for example, input information of the input unit 11, results of the optical simulation executed by the optical simulator 20, and the like) to be used in the processing related to S1 to S4 or the like.

The determination section 145 is a processing unit configured to make various determinations in the processing related to S1 to S4 by comparing with, for example, inputted determination values.

The optical simulator 20 is an information processing apparatus configured to execute the optical simulation by a known ray-tracing method under the conditions set by the information processing apparatus 10. The optical simulator 20 executes the optical simulation under the conditions set by the information processing apparatus 10 by communication via the communication unit 13, and returns results of the optical simulation (for example, a calculation result of ray-tracing, a calculation result of coupling efficiency, and the like) to the information processing apparatus 10. For example, the optical simulator 20 includes a model generator 21, a ray-tracing calculator 22, and a coupling efficiency calculator 23.

The model generator 21 is a processing unit configured to generate a model (arrangement of the lens block 1, light emitting element 3a, and light receiving unit 3b, the medium, and the like) to be subjected to the optical simulation based on various parameters notified from the information processing apparatus 10.

The ray-tracing calculator 22 is a processing unit configured to perform calculation by the ray-tracing method in the model generated by the model generator 21. For example, the ray-tracing calculator 22 calculates the ray-tracing of the light emitted from the light emitting element 3a.

The coupling efficiency calculator 23 is a processing unit configured to calculate the coupling efficiency of the light travelling from the light emitting element 3a to the light receiving unit 3b. For example, the coupling efficiency calculator 23 calculates the coupling efficiency by calculating a ratio between the intensity of the light emitted from the light emitting element 3a and the intensity of the light received by the light receiving unit 3b, based on the result of the ray-tracing calculated by the ray-tracing calculator 22.

In the optical simulation by the optical simulator 20, it is assumed that the reflection of the lens surfaces 1a and 1b, the reflection of the light receiving unit 3b, the loss in the medium (liquid) 2b, and the loss in the lens block 1 are negligible because of their very little influence on the lens design values.

[Operations]

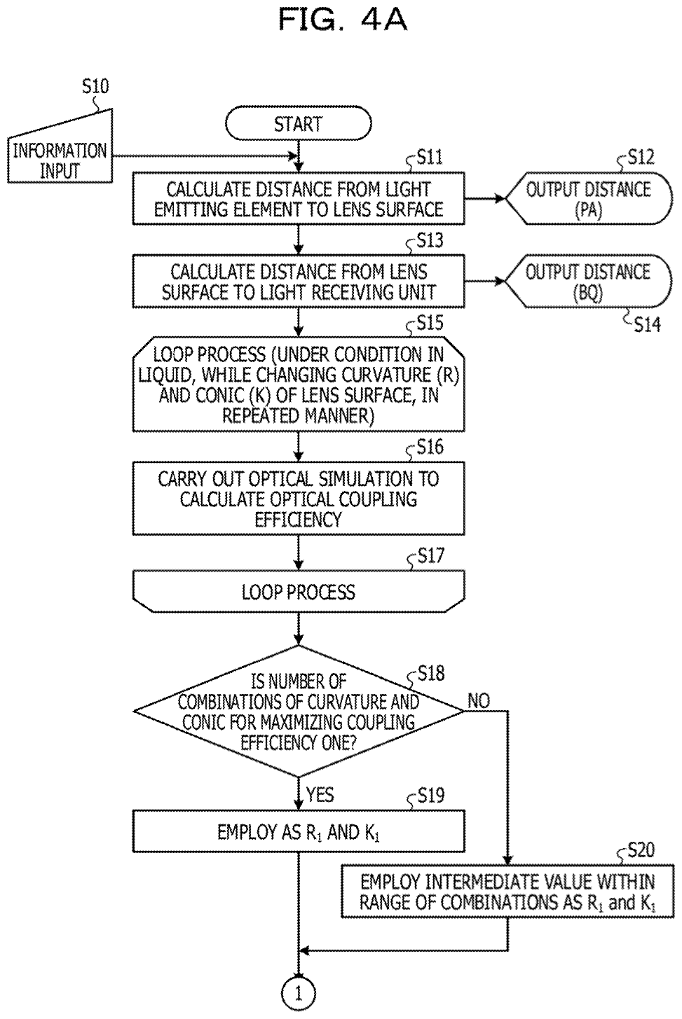

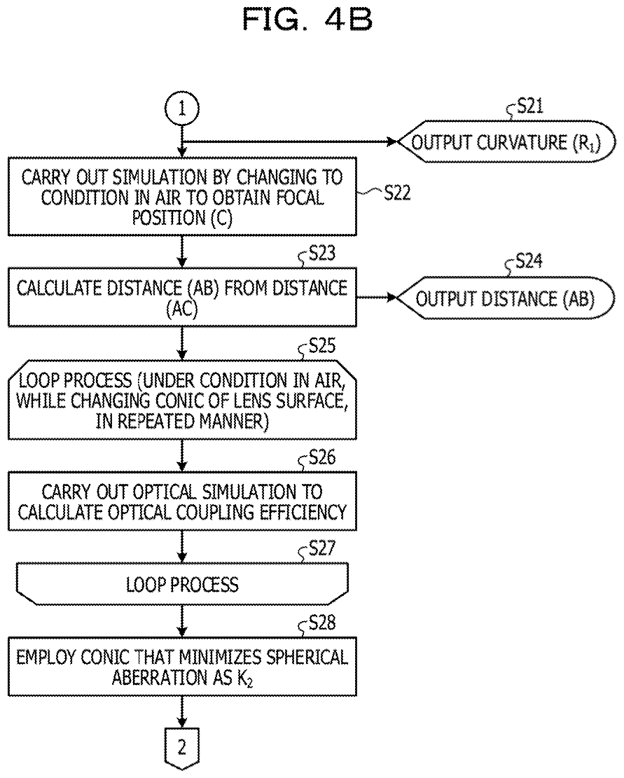

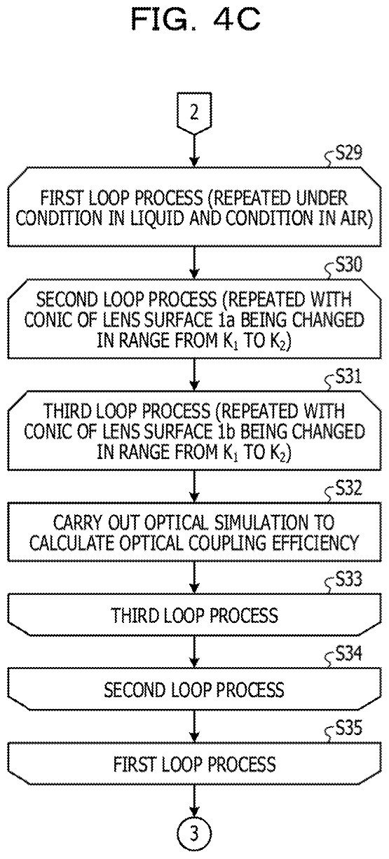

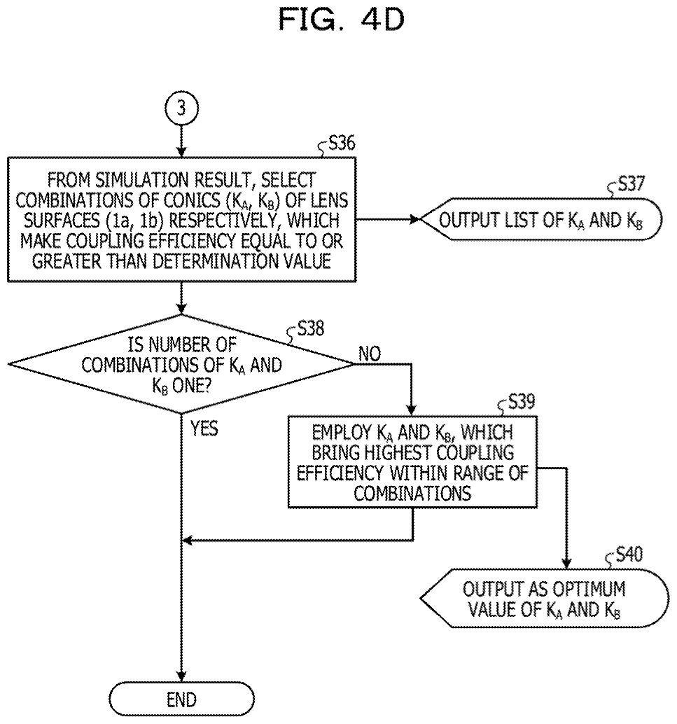

FIG. 4A to FIG. 4D are flowcharts illustrating an example of operations of the information processing apparatus 10 according to the embodiment. As illustrated in FIG. 4A to FIG. 4D, when the process is started, the input unit 11 accepts information inputted by a user (for example, a designer) (S10). For example, the input unit 11 accepts the information input such as refractive index information, light emitting element information, lens size information, light receiving unit information, and determination values.

Next, the distance calculation section 141 calculates a distance (PA) from the light emitting element 3a to the lens surface 1a based on the inputted information (S11). The display unit 12 outputs the distance (PA) calculated by the distance calculation section 141 (S12).

For example, based on the light emitting element information and the lens size information, the distance calculation section 141 obtains the distance (PA) from the light emitting element 3a to the lens surface 1a, where all of the light beams emitted from the light emitting element 3a are incident on the lens surface 1a. For example, it is possible to obtain the distance (PA) with the expression of distance (PA)=lens radius*lens surface usage rate/tan (light spread angle). As an example, when the lens radius is 125 μm, the lens surface usage rate is 0.8, and the light spread angle is 11 degrees, the distance (PA) comes to be 514 μm with the equation of distance (PA)=125 μm*0.8/tan 11 degrees.

Subsequently, the distance calculation section 141 calculates a distance (BQ) from the lens surface 1b to the light receiving unit 3b, based on the inputted information (S13). The display unit 12 outputs the distance (BQ) calculated by the distance calculation section 141 (S14).

For example, similarly to S11, the distance calculation section 141 obtains the distance (BQ) from the lens surface 1b to the light receiving unit 3b, where all of the light beams emitted from the lens surface 1b are received by the light receiving unit 3b, based on the light receiving unit information and the lens size information (S13). In the present embodiment, since the diameter of the light receiving unit is sufficiently large, the distance (BQ) from the lens surface 1b to the light receiving unit 3b is assumed to be equal to the distance (PA).

Then, the control unit 14 carries out processing (S15 to S20) to obtain the curvature (R) and the conic of the lens surface for causing the light beams having passed through the lens surface 1a to become parallel light beams in the lens block 1 in the medium (liquid) 2b.

For example, the parameter control section 142 carries out a loop process in which, while changing combinations of the curvature (R) and the conic (K) of the lens surfaces 1a and 1b under a condition in the medium (liquid) 2b, the optical simulation is repeated to obtain coupling efficiency of each combination (S15 to S17).

For example, the parameter control section 142 sets parallel light sources, equal to lens radius*lens usage rate, from the inside of the lens block 1 toward the lens surface 1a, and sets the light emitting element 3a of the simulation at the light emitting element position. Next, the parameter control section 142 carries out the optical simulation by combining the curvatures in a range from the lens radius (for example, 125 μm) to 1.2 times the lens radius (for example, 150 μm) and the conics in a range from −1.0 to −3.

Then, based on the coupling efficiency of each combination obtained in the loop process of S15 to S17, the determination section 145 determines whether the number of combinations of the curvature (R) and the conic (K) for maximizing the coupling efficiency is one (S18).

In a case where there is one combination of the curvature (R) and the conic (K) for maximizing the coupling efficiency (S18: Yes), the determination section 145 employs the one combination of the curvatures (R) and the conic (K) (a combination of parameters that brings the highest coupling efficiency) as a curvature (R₁) and a conic (K₁) (S19).

In a case where there exist a plurality of combinations of the curvature (R) and the conic (K) for maximizing the coupling efficiency (S18: No), the determination section 145 employs an intermediate value within the range of the combinations as the curvature (R₁) and the conic (K₁) (S20).

Next, the display unit 12 outputs the curvature (R₁) employed in S19 or S20 (S21). In the case where the distance (PA) from the light emitting element 3a to the lens surface 1a equals the distance (BQ) from the lens surface 1b to the light receiving unit 3b, the curvature and the conic of the lens surface 1b also use R₁ and K₁, respectively. As a result, the parallel light beams in the lens block 1 are focused, after passing through the lens surface 1b, at the light receiving unit 3b.

Then, the parameter control section 142 applies K₁ to the curvature of the lens surfaces 1a and 1b, and carries out the optical simulation by changing the condition from the condition in the medium (liquid) 2b to the condition in the medium (air) 2a (by changing the refractive index), thereby obtaining a focal position (C) of the light beams having passed through the lens surface 1a (S22). Here, the distance from the lens surface 1a to the focal position (C) is taken as AC.

Subsequently, the distance calculation section 141 calculates the distance (AB) between the lens surface 1a and the lens surface 1b, in which the focal position (C) is the center 1c of the lens block 1, from the distance (AC) (S23). The display unit 12 outputs the distance (AB) calculated by the distance calculation section 141 (S24). For example, the distance calculation section 141 obtains the distance AB as the distance AB being equal to AC*2. For example, when AC is 640 μm, AB is calculated as 640*2=1280 μm.

Next, the control unit 14 applies K₁ to the curvature of the lens surfaces 1a and 1b, and then carries out processing (S25 to S28) to obtain a conic for minimizing the spherical aberration, at the focal position (C), of the light beams having passed through the lens surface 1a under the condition in the medium (air) 2a.

For example, the parameter control section 142 carries out a loop process (S25 to S27) in which, while changing the conic of the lens surface 1a under the condition in the medium (air) 2a, the optical simulation is repeated to obtain coupling efficiency of each conic.

Next, based on the coupling efficiency of each conic obtained in the loop process of S25 to S27, the determination section 145 employs, as K₂, the conic that minimizes the spherical aberration at the focal position (C) (S28).

Subsequently, the control unit 14 applies K₁ to the curvature of the lens surfaces 1a and 1b, and carries out processing (S29 to S35), in which the optical simulation is repeated while the conic of the lens surfaces 1a and 1b being changed in a range from K₁ to K₂, so as to obtain the coupling efficiency of each of the conditions in the medium (air) 2a and the medium (liquid) 2b.

For example, the parameter control section 142 carries out a first loop process (S29 to S35) repeated with the refractive index under the condition in the medium (liquid) 2b and with the refractive index under the condition in the medium (air) 2a, respectively. The parameter control section 142 carries out, within the first loop process, a second loop process (S30 to S34) repeated with the conic of the lens surface 1a being changed in the range from K₁ to K₂. The parameter control section 142 carries out, within the second loop process, a third loop process (531 to 533) repeated with the conic of the lens surface 1b being changed in the range from K₁ to K₂. The parameter control section 142, after changing the parameter conditions as described above, carries out the optical simulation to obtain the coupling efficiency (S32).

Next, from the simulation result of S29 to S35, the determination section 145 selects combinations of conics (K_{A}, K_{B}) of the lens surfaces 1a and 1b respectively, which make the coupling efficiency equal to or greater than a determination value set by the user (S36). The display unit 12 outputs a list of the combinations of conics (K_{A}, K_{B}) selected by the determination section 145 (S37).

Subsequently, the determination section 145 determines whether the number of selected combinations of conics (K_{A}, K_{B}) is one (S38). In the case where the number of combinations of conics (K_{A}, K_{B}) is one (S38: Yes), the control unit 14 ends the process because one combination that brings the highest coupling efficiency has been outputted in S37.

In the case where a plurality of combinations of conics (K_{A}, K_{B}) are present (S38: No), the determination section 145 employs a combination of conics (K_{A}, K_{B}) which brings the highest coupling efficiency within the range of the combinations (S39). Then, the display unit 12 outputs the combination of conics (K_{A}, K_{B}) employed in S39 as an optimum value (S40), and ends the process.

[Effects]

As described above, the information processing apparatus 10 obtains the curvature (R₁) and the first conic (K₁) for causing the light beams inputted to the lens block 1 to become parallel light beams when the lens block 1 is set in the medium (liquid) 2b, with regard to the two lens surfaces 1a and 1b of input and output of the lens block 1. Further, based on the obtained curvature, the information processing apparatus 10 obtains the distance (AB) between the lens surfaces and the second conic (K₂) for causing the light beams inputted to the lens block 1 to focus at the center between the lens surfaces 1a and 1b when the lens block 1 is set in the medium (air) 2a. The information processing apparatus 10 sets the lens block 1 based on the obtained curvature and distance at a location between the light emitting element 3a and the light receiving unit 3b, and obtains combinations of optical coupling efficiency in the medium (air) 2a and the medium (liquid) 2b when the conic of the lens surfaces 1a and 1b is changed between the first conic and the second conic. Furthermore, the information processing apparatus 10 outputs the obtained curvature, the obtained distance, and a third conic of the lens surfaces 1a and 1b, which brings the coupling efficiency satisfying a predetermined condition among the obtained combinations of coupling efficiency.

The output from the lens block 1 allows the user to easily design a lens having good coupling efficiency in the different media of the medium (air) 2a and the medium (liquid) 2b. By applying the lens block 1, the lenses of which have been designed in the manner discussed above, to an optical module of a server system or the like, it is possible to efficiently transmit optical signals without generating a cost for providing an additional mechanism or the like, in any of the cases of usage in the air environment and in the immersion environment.

Further, the information processing apparatus 10 obtains combinations of coupling efficiency when the conic of each of the two lens surfaces 1a and 1b is changed between the first conic (K₁) and the second conic (K₂). Moreover, the information processing apparatus 10 outputs the conics (K_{A}, K_{B}) of the two lens surfaces 1a and 1b respectively, which bring the coupling efficiency satisfying a predetermined condition, as the third conic. Thus, the user is able to carry out the lens design of each of the two lens surfaces 1a and 1b using the conics (K_{A}, K_{B}) obtained from the information processing apparatus 10.

The information processing apparatus 10 outputs, as the third conic, the conic of the two lens surfaces 1a and 1b (optimum value of K_{A} and K_{B}), which brings the highest coupling efficiency among the obtained combinations of coupling efficiency. Thus, the user is able to easily carry out the lens design with good coupling efficiency, for example, in any of the cases of usage environment in the air and in the liquid.

[Others]

The constituent elements of the units or sections illustrated in the drawings do not necessarily have to be physically configured as illustrated therein. For example, specific forms of distribution and integration of the units and sections may not be limited to those illustrated in the drawings, and all or some of the units and sections may be configured to be functionally or physically distributed or integrated in any unit based on various loads and usage statuses.

For example, the distance calculation section 141, the parameter control section 142, and the simulator call section 143 may be integrated. The control unit 14 may be configured to have the functions of the model generator 21, the ray-tracing calculator 22, and the coupling efficiency calculator 23. For example, the information processing apparatus 10 may be configured to also serve as the optical simulator 20. The processing illustrated in the drawings may not be carried out in the foregoing order. Two or more of the processing may be simultaneously carried out without contradicting the details of the processing.

All or some of the various processing functions to be executed by the devices may be executed on a CPU (or a microcomputer, such as an MPU or a microcontroller unit (MCU)). It is to be understood that all or any part of the various processing functions may be enabled by a program analyzed and executed by a CPU (or a microcomputer such as an MPU or an MCU) or may be executed by hardware using wired logic. In addition, the various processing functions may be enabled by cloud computing in which a plurality of computers cooperate with each other.

[Hardware Configuration]

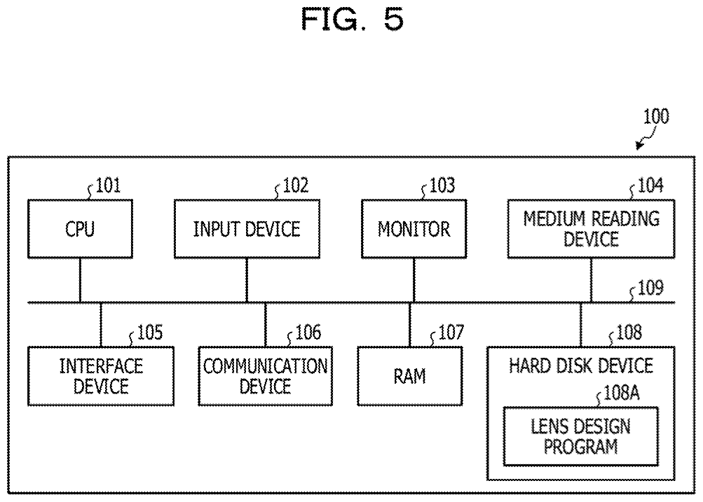

The various processing described above in the embodiments may be enabled by causing a computer to execute a program prepared in advance. An example of a computer configured to execute a lens design program having the same functions as those of the above-discussed embodiments will be described below. FIG. 5 is a block diagram illustrating an example of a computer configured to execute the lens design program.

As illustrated in FIG. 5, a computer 100 includes a CPU 101 configured to execute various arithmetic processing, an input device 102 configured to receive data input, and a monitor 103. The computer 100 includes a medium reading device 104 configured to read a program and the like from a recording medium, an interface device 105 to be coupled with various devices, and a communication device 106 to be coupled to another information processing apparatus or the like by wired or wireless communication. The computer 100 also includes a RAM 107 configured to temporarily store various information, and a hard disk device 108. The devices 101 to 108 are coupled to a bus 109.

The hard disk device 108 stores a lens design program 108A having the same functions as those of the processing units of the distance calculation section 141, parameter control section 142, simulator call section 143, and determination section 145 illustrated in FIG. 3. In the hard disk device 108, various types of data relating to the distance calculation section 141, parameter control section 142, simulator call section 143, and determination section 145 are stored. The input device 102 receives input of various kinds of information, such as operation information, from a user of the computer 100, for example. The monitor 103 displays various kinds of screens, such as a display screen, for the user of the computer 100, for example. To the interface device 105, for example, a printing device is coupled. The communication device 106 is coupled to a network (not illustrated) and transmits and receives various kinds of information to and from another information processing apparatus.

The CPU 101 executes various processing by reading out the lens design program 108A stored in the hard disk device 108, loading the lens design program 108A on the RAM 107, and executing the lens design program 108A. The lens design program 108A is able to cause the computer 100 to function as the control unit 14.

The above-described lens design program 108A may not be stored in the hard disk device 108. For example, the computer 100 may read out and execute the lens design program 108A stored in a recording medium readable by the computer 100. The recording medium readable by the computer 100 corresponds to, for example, a portable recording medium, such as a compact disc read-only memory (CD-ROM), a digital versatile disc (DVD), or a Universal Serial Bus (USB) memory, a semiconductor memory, such as a flash memory, or a hard disk drive. The lens design program 108A may be stored in a device coupled to, for example, a public network, the Internet, or a LAN, and may be read out from the device and executed by the computer 100.

The following appendices are disclosed in the above embodiments.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A non-transitory computer-readable recording medium having stored therein a lens design program for causing a computer to execute a process, the process comprising:
obtaining a curvature and a first conic with respect to two lens surfaces of input and output of an optical member in which light beams inputted to the optical member become parallel light beams when the optical member is in a first medium;
obtaining, based on the obtained curvature, a distance between the two lens surfaces and a second conic that cause the light beams inputted to the optical member to focus at a center between the two lens surfaces when the optical member is in a second medium;
obtaining combinations of optical coupling efficiency in the first medium and the second medium in a case where the optical member based on the obtained curvature and the obtained distance is set between a light emitter of light beams and a light receiver, and then the conic of the two lens surfaces is changed between the first conic and the second conic; and
outputting the obtained curvature, the obtained distance, and a third conic of the two lens surfaces that brings coupling efficiency satisfying a predetermined condition among the obtained combinations of coupling efficiency.

2. The non-transitory computer-readable recording medium according to claim 1, wherein
the obtaining of the combinations of coupling efficiency is configured to obtain the combinations of coupling efficiency when the conic of each of the two lens surfaces is changed between the first conic and the second conic, and
the outputting is configured to output, as the third conic, the conic of each of the two lens surfaces that brings the coupling efficiency satisfying the predetermined condition.

3. The non-transitory computer-readable recording medium according to claim 1, wherein
the outputting is configured to output, as the third conic, the conic of the two lens surfaces that brings a maximum coupling efficiency among the obtained combinations of coupling efficiency.

4. The non-transitory computer-readable recording medium according to claim 1, wherein
the first medium is a refrigerant filling a periphery of the optical member, and
the second medium is air.

5. A lens design method causing a computer to execute a process, the process comprising:
obtaining a curvature and a first conic with respect to two lens surfaces of input and output of an optical member in which light beams inputted to the optical member become parallel light beams when the optical member is in a first medium;
obtaining, based on the obtained curvature, a distance between the two lens surfaces and a second conic that cause the light beams inputted to the optical member to focus at a center between the two lens surfaces when the optical member is in a second medium;
obtaining combinations of optical coupling efficiency in the first medium and the second medium in a case where the optical member based on the obtained curvature and the obtained distance is set between a light emitter of light beams and a light receiver, and then the conic of the two lens surfaces is changed between the first conic and the second conic; and
outputting the obtained curvature, the obtained distance, and a third conic of the two lens surfaces that brings coupling efficiency satisfying a predetermined condition among the obtained combinations of coupling efficiency.

6. The lens design method according to claim 5, wherein
the obtaining of the combinations of coupling efficiency is configured to obtain the combinations of coupling efficiency when the conic of each of the two lens surfaces is changed between the first conic and the second conic, and
the outputting is configured to output, as the third conic, the conic of each of the two lens surfaces that brings the coupling efficiency satisfying the predetermined condition.

7. The lens design method according to claim 5, wherein
the outputting is configured to output, as the third conic, the conic of the two lens surfaces that brings a maximum coupling efficiency among the obtained combinations of coupling efficiency.

8. The lens design method according to claim 5, wherein
the first medium is a refrigerant filling a periphery of the optical member, and
the second medium is air.

9. An information processing apparatus comprising:
a memory; and
a processor coupled to the memory and configured to:
obtain a curvature and a first conic with respect to two lens surfaces of input and output of an optical member in which light beams inputted to the optical member become parallel light beams when the optical member is in a first medium, obtain, based on the obtained curvature, a distance between the two lens surfaces and a second conic that cause the light beams inputted to the optical member to focus at a center between the two lens surfaces when the optical member is in a second medium, and obtain combinations of optical coupling efficiency in the first medium and the second medium in a case where the optical member based on the obtained curvature and the obtained distance is set between a light emitter of light beams and a light receiver, and then the conic of each of the two lens surfaces is changed between the first conic and the second conic; and
output the obtained curvature, the obtained distance, and a third conic of the two lens surfaces that brings coupling efficiency satisfying a predetermined condition among the obtained combinations of coupling efficiency.

10. The information processing apparatus according to claim 9, wherein
the processor obtains the combinations of coupling efficiency when the conic of each of the two lens surfaces is changed between the first conic and the second conic, and
output, as the third conic, the conic of each of the two lens surfaces that brings the coupling efficiency satisfying the predetermined condition.

11. The information processing apparatus according to claim 9, wherein
the processor is configured to output, as the third conic, the conic of the two lens surfaces that brings a maximum coupling efficiency among the obtained combinations of coupling efficiency.

12. The information processing apparatus according to claim 9, wherein
the first medium is a refrigerant filling a periphery of the optical member, and
the second medium is air.
